(19) United States
(12) Patent Application Publication
(10) Pub. No.: US 2014/0144666 A1
(43) Pub. Date: May 29, 2014

(54) Electronic Device with Electrically Conducting Cover Connection

(71) Applicant: SMA Solar Technology AG, Niestetal (DE)

(72) Inventor: Swetlana Lisitschew, Kassel (DE)

(73) Assignee: SMA Solar Technology AG, Niestetal (DE)

(21) Appl. No.: 14/078,608

(22) Filed: Nov. 13, 2013

(30) Foreign Application Priority Data
Nov. 27, 2012 (DE) 10 2012 111 491.9

(51) Int. Cl. H05K 5/02

(52) U.S. Cl. CPC H05K 5/0247
USPC 174/50

(57) ABSTRACT

An electronic device is provided with a base as a first housing part and a cover as a second housing part, the first housing part and the second housing part being formed at least partially from conductive material. In an assembled state, the electronic device is electrically connected by a fastening pair respectively belonging to one of the two housing parts, the fastening pair having a pin with at least three pressure edges and a recess with an opening cross section adapted to the pin. In the assembled state, the pin protrudes into the recess in such a way that a holding force between the two housing parts is exerted between the pressure edges and the walls of the recess.

### REFERENCE TO RELATED APPLICATIONS

This application claims priority to German application number 10 2012 111 491.9 filed on Nov. 27, 2012, the contents of which are hereby incorporated by reference.

### FIELD

The disclosure relates to an electronic device, in particular an inverter, especially a modular inverter. The electronic device comprises housing parts which in an assembled state are electrically connected to one another.

### BACKGROUND

Electronic devices are often accommodated in conductive housing parts and these are connected to a reference potential such as earth potential. This ensures the elimination of risks caused by contact of the housing, arising as a result of electric potentials that are built up inside the housing during operation, being transferred to parts of the housing. In particular in the case of inverters for photovoltaics, dangerous voltages of several hundred volts may occur as a result of a connected solar generator, and so reliable earthing of all the housing parts that could be contacted is required.

It is known to screw the individual housing parts to one another, in order to achieve reliable fixing of the housing parts to one another and at the same time reliable electrical connection between the parts. In this respect it is required specifically in the case of painted or powder-coated housing parts additionally to place under each of the screws a contact plate, which penetrates the coating during screwing in order to ensure the electrical contact between the screw and the housing part. The effort that is involved in assembly is considerable in the case of this connection technique, and so there is a need for the associated costs to be saved by providing other connection techniques.

The document DE 10 2009 008 527 discloses a housing for sensor electronics in which a cover has web-shaped formations, which during assembly of the cover engage in corresponding formations of the housing and achieve mechanical securement of the cover by plastic-elastic deformation. The cover may subsequently be welded or adhesively bonded to the housing.

### SUMMARY

An electronic device according to the disclosure has a base as a first housing part and a cover as a second housing part. Both housing parts are formed completely or at least partially from conductive material or have a conductive coating and, in an assembled state of the electronic device, are electrically connected to one another by a fastening pair, which comprises a pin with at least three pressure edges and a recess with an opening cross section adapted to the pin. The pin belongs to one of the two housing parts and the recess belongs to the other. In the assembled state, the pin protrudes into the recess in such a way that a holding force between the two housing parts is exerted between the pressure edges of the pin and the walls of the recess.

In another configuration of the electronic device, the pin is a component part of the cover and is, in one embodiment, formed together with the cover as a one-piece housing part. Correspondingly, the recess may be formed together with the base as a one-piece housing part. Alternatively, however, the pin may likewise be a component part of the base and be formed with it as a one-piece housing part, with the recess as part of the cover. It is advantageous in one embodiment to produce the base and/or the cover of the electronic device by means of a diecasting process, in particular an aluminium diecasting process. In this way, it is conceivable in particular to produce the housing parts and the fastening elements in one step, without any further working being required.

In an embodiment according to the disclosure, the base and the cover are provided with an adhesive seal, in particular a silicone seal, in order to form together a sealed housing of the electronic device. It is optionally conceivable to additionally provide a connection plate, which is mounted between the base and the cover and is connected to the base and the cover by way of an adhesive seal. In an assembled state, the electronic device is in this case held together both by the holding force of the fastening pair and by the adhesive force of the adhesive seal.

The pressure edges of the pin in combination with the walls of the recess establish a reliable electrical connection between the two housing parts. A configuration that is advantageous in one embodiment is one in which the pin has a triangular cross section, and consequently precisely three pressure edges, even though for example cross-sectional forms with four, five or more pressure edges are not ruled out. The recess is formed in an opening cross section that is adapted to the assigned pin. The inner walls of the recess are formed in this case such that the distance between the inner wall regions, which in the assembled state are in contact with the pressure edges of the pin, have a slightly smaller inner distance from one another than the outer distance between the corresponding regions of the pressure edges of the pin. In this way, a high pressing force of the pressure edges on the inner walls of the recess is exerted in the assembled state, and at the same time canting of the pin on insertion into the recess is avoided. A sufficiently high pressing force of the pressure edges on the inner walls of the recess leads to local cold welding of the components, and consequently to a particularly reliable electrical and mechanical connection between the housing parts. This cold welding effect can be enhanced by suitable treatment of the surfaces of the pin and/or the recess. The recess may advantageously be round. Furthermore, the pin or the recess may be provided with surface structures such as steps, channels, undercuts or roughenings, which improve the electrical and mechanical properties of the connection between the housing parts after they have been joined together and for example perform an engaging function.

In one embodiment, the pin is provided with a conical form, in which the cross section of the pin decreases from its root to its tip continuously or in steps. In one embodiment, the angle of inclination of the conical form of the pin and the angle of inclination of the inner walls of the recess are in this case made to match one another, and so, after insertion of the pin into the recess, a uniform pressing force between the pressure edges of the pin and the inner wall of the recess is achieved over the length of the pressure edges.

Even if it is conceivable to connect the cover and the base to one another additionally by screws, in an embodiment according to the disclosure of the electronic device the cover and the base are electrically and mechanically connected to one another in the assembled state by a screw-less connection. In this way, the assembly of the electronic device can be performed in a particularly simple and low-cost manner.

The electronic device may advantageously be an inverter, in particular an inverter for photovoltaics. The assembly technique can bring its special advantages to bear in particular when it is used inside a modular inverter, since these inverters have a small structural form and a low weight and are produced in large numbers.

Advantageous developments of the disclosure are provided by the patent claims, the description and the drawings. The advantages mentioned in the present description of features or of combinations of multiple features are only examples and may come into effect alternatively or cumulatively without the advantages of the embodiments according to the disclosure necessarily having to be achieved. The embodiments that are disclosed in the description serve a person skilled in the art as options for the implementation of the disclosure, though the disclosure is not restricted to these example embodiments. A person skilled in the art will regard these example embodiments as suggestions for deriving other refinements of the disclosure—including with variants of the implementation of the features thereof that are not specifically disclosed here—on the basis of the actual need of the individual case.

The features mentioned in the patent claims and the description should be understood with respect to their number such that precisely this number or a greater number than the number mentioned is present, without explicit use of the adverb “at least” being required. If, on the other hand, only the precise number of a feature is to be specified, the adjective “precisely” is used before the respective feature. These features may be supplemented by other features or be the only features of the respective product.

### BRIEF DESCRIPTION OF THE DRAWINGS

The disclosure is explained in more detail and described below on the basis of example embodiments with reference to the appended drawings.

FIG. 1 shows an exploded drawing of components of an electronic device according to the disclosure;

FIG. 2 shows a perspective representation of an embodiment of a cover according to the disclosure;

FIG. 3 shows a cutout of a cover with a configuration of a pin according to the disclosure;

FIG. 4 shows a perspective representation of an embodiment of a base according to the disclosure;

FIG. 5 shows a cutout of a base with a configuration of a recess according to the disclosure.

### DETAILED DESCRIPTION

The disclosure addresses the problem of providing an electronic device in which the cover and the base can be assembled in a particularly simple and low-cost manner in such a way that, after assembly, there is an electrical connection permanently between them.

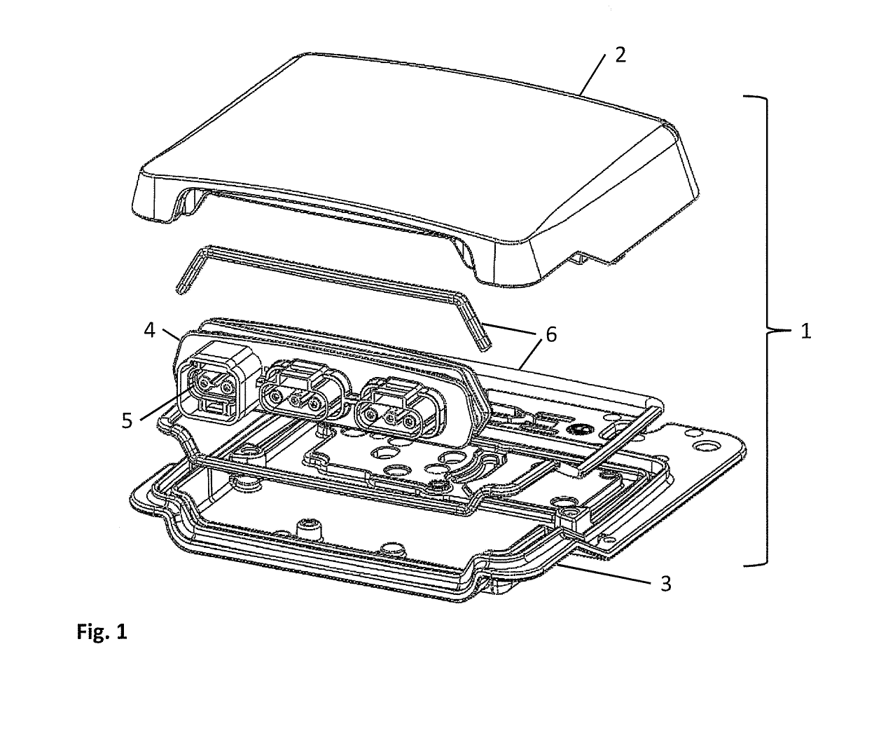

FIG. 1 shows housing components of an electronic device 1 in an exploded drawing. A cover 2 forms together with a base 3 and a connection plate 4 a housing of the electronic device 1, which is represented here as a modular inverter. A printed circuit board (not shown here) with electronic components may be arranged inside the housing. Electrical connections for the electronic components may be led out from the housing with the aid of plug-in connections 5, which are part of the connection plate 4. The impermeability of the housing is achieved with the aid of seals 6, which are arranged between the cover 2, the connection plate 4 and the base 3. These seals may be rubber seals, or similarly adhesive seals, in particular silicone seals, which are placed or injection-moulded into a corresponding groove of one or more of the housing components before the housing is joined together. During the joining together of the housing, corresponding cooperating sealing surfaces of other housing components are pressed onto the sealing surface and thus seal the housing against the penetration of contamination and moisture. Since the seals are typically produced from an electrically nonconducting material, an electrical connection between the housing parts cannot be achieved by way of the seal.

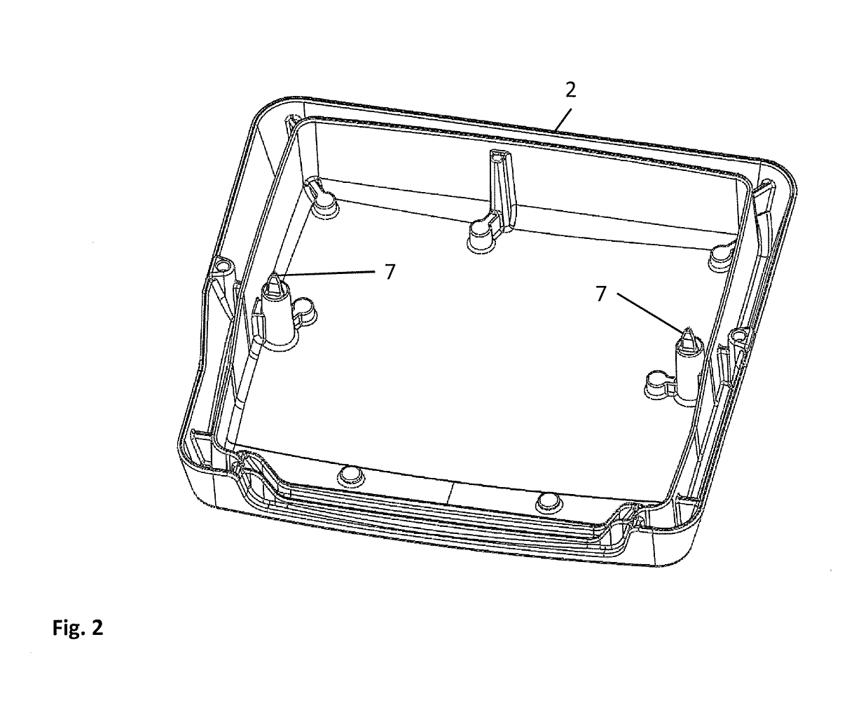

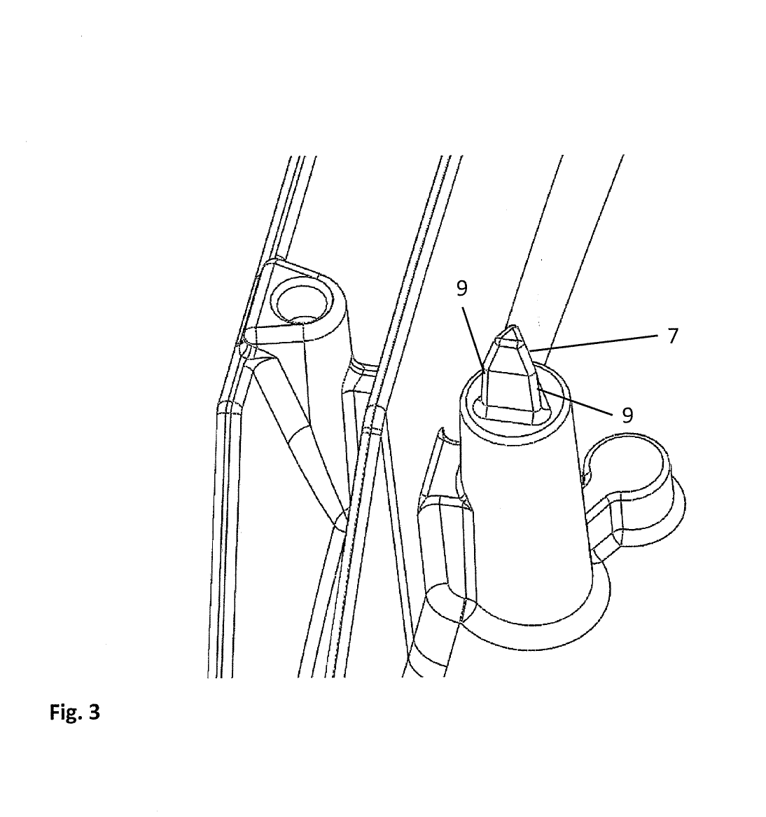

FIG. 2 shows a cover 2 of an electronic device 1 in a perspective representation. Represented in the inner region of the cover are two pins 7, which are arranged on opposite sides of the cover 2 in one embodiment. The form of the pins is shown more specifically in the cutout of FIG. 3. The pin has here a triangular cross section, and so three pressure edges 9 are obtained. In one embodiment the cross section of the pin 7 decreases from the root to the tip, and so a conical form is obtained. One of the effects of the conical form is that of centring the pin in connection with a corresponding recess during assembly. The centring can be improved further by providing in the region of the tip of the pin 7 a region in which the cross section tapers more.

It is conceivable to distribute any number of pins over the housing part, in this case the cover 2. In one embodiment, however, at least two pins are provided, to achieve a reliable electrical connection and a reliable holding force of the cover after assembly.

In a one-piece version, the pins 7 are configured as part of the cover 2 and are produced together with the cover while it is being formed. Although it is conceivable to insert the pins 7 into recesses of the cover 2 only after production of the cover 2, as independent components, this would mean that production involves increased effort due to an additional assembly step. The cover 2 could be produced for example in an aluminium diecasting process, whereby the pins can be produced together with the cover without any additional effort and without subsequent working. It goes without saying, however, that subsequent working of the pins may be provided, for example in order to improve further the electrical properties or the holding properties of the pin inserted into a recess.

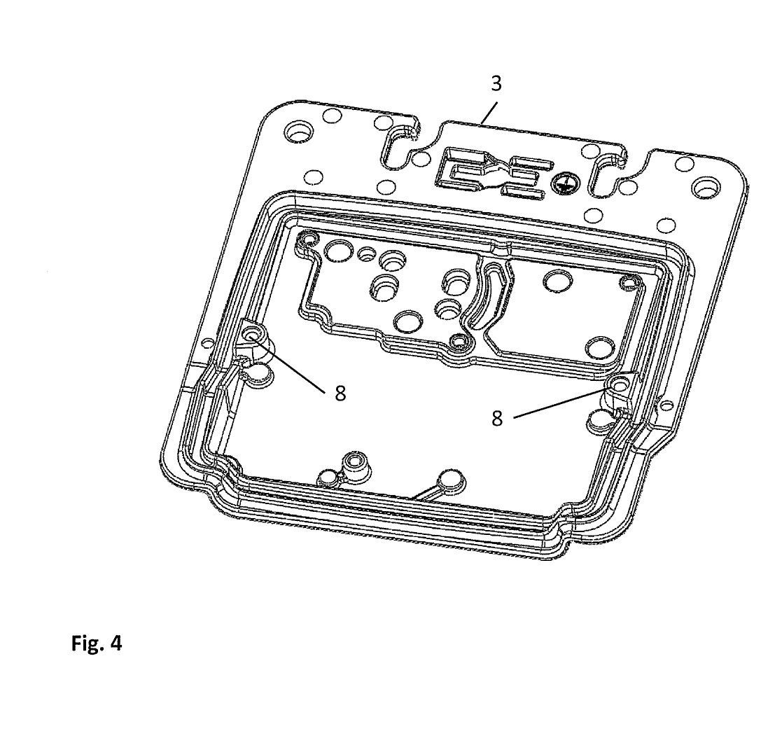

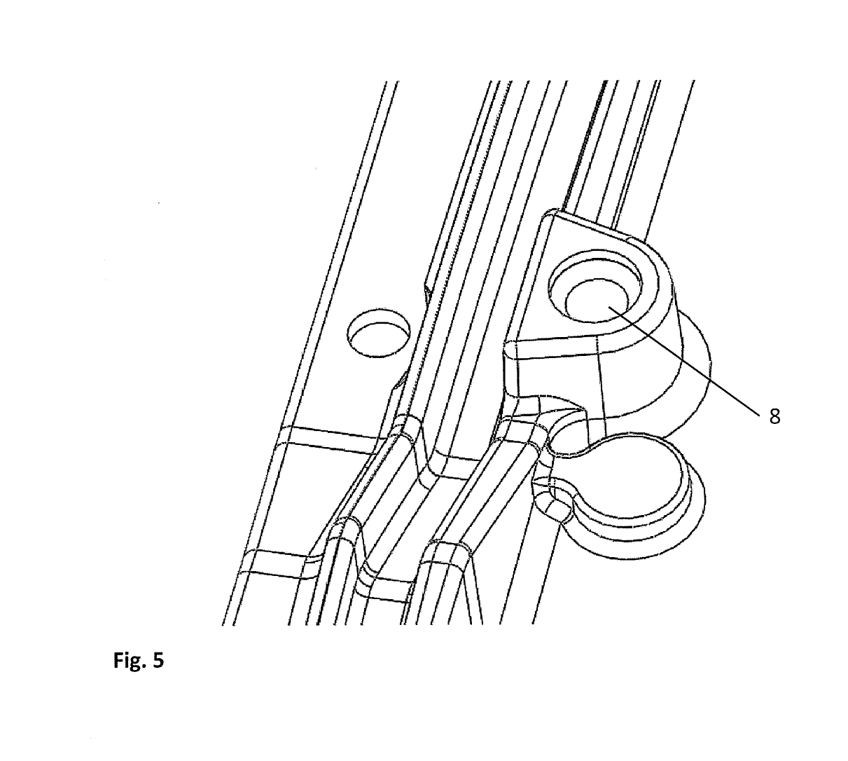

FIG. 4 shows a base 3 of the electronic device 1 in a perspective representation. Cooperating with the two pins 7 from FIG. 2, the base 2 has recesses 8, which are arranged such that the pins 7 are inserted into the recesses 8 during the assembly of the cover 2 onto the base 3. The recesses 8 are represented in detail in the drawing of the cutout of FIG. 5. The diameter of the recesses 8 is chosen such that, when the pins 7 are inserted into the recesses 8 during assembly, a compressive force is produced between the pressure edges 9 of the pin 7 and the inner walls of the assigned recesses 8. The compressive force is sufficient to achieve a deformation of the pin 7 or the recess 8 and a cold welding of the pressure edges 9 and the inner walls of the recess 8. In this way, apart from the electrical connection between the housing parts, a holding force between the cover and the base is achieved, sufficient to hold the two housing parts together. When an adhesive seal 6 is used, the holding force between the base 3 and the cover 2 is maintained as long as the adhesive action of the seal is sufficient to hold the two housing parts together. In this way it is possible after the joining together of the housing parts to perform further assembly or transporting steps without having to wait for the seal to cure, and without a pressing force having to be applied by additionally fitted clamping elements. The assembly process is thus simplified and sped up considerably.

As an alternative to the described production of the cover and the base by means of a diecasting process, in particular an aluminium diecasting process, a plastics injection-moulding process may also be used. After they have been produced, the parts of plastic are partially—for example on the surfaces facing the inside of the device—or completely coated in an electrically conducting manner, for example by painting or vapour deposition. They can consequently be regarded in the sense of the present disclosure as produced from conductive material. The electrically conducting connection between the parts is performed in the same way as described further above.

1. An electronic device, comprising:
a base comprising a first housing part; and
a cover comprising a second housing part,
wherein the first housing part and the second housing part are formed at least partially from conductive material and, in an assembled state of the electronic device are electrically connected by a fastening pair, components of the fastening pair respectively belonging to one of the first and second housing parts,
wherein the fastening pair comprises a pin with at least three pressure edges and a recess with an opening cross section defined by walls adapted to the pin, and
wherein in the assembled state, the pin protrudes into the recess such that a holding force between the first and second housing parts is exerted between the pressure edges and the walls of the recess.

2. The electronic device according to claim 1, wherein the pin and the cover are formed as a one-piece housing part.

3. The electronic device according to claim 1, wherein the pin and the base are formed as a one-piece housing part.

4. The electronic device according to claim 1, further comprising an adhesive seal provided between the base and the cover.

5. The electronic device according to claim 1, further comprising:
a connection plate; and
an adhesive seal provided between the connection plate and the base, and provided between the connection plate and the cover.

6. The electronic device according to claim 1, wherein the pin has precisely three pressure edges.

7. The electronic device according to claim 1, wherein the pin has a conical form.

8. The electronic device according to claim 1, wherein the pin is produced by the diecasting process from aluminium.

9. The electronic device according to claim 1, wherein the first and second housing parts in the assembled state are connected via the fastening pair in a screw-less connection.

10. The electronic device according to claim 1, wherein the electronic device is an inverter.
